(19) United States
(12) Patent Application Publication
(10) Pub. No.: US 2008/0179186 A1
(43) Pub. Date: Jul. 31, 2008

(54) THIN FILM FORMING APPARATUS

(76) Inventors: Kazuhiro Shimura, Toyama (JP); Kenji Shirako, Toyama (JP); Kosuke Takagi, Toyamashi (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 12/014,279

(22) Filed: Jan. 15, 2008

(30) Foreign Application Priority Data
Jan. 17, 2007 (JP) 2007-008110

(51) Int. Cl. C23C 14/46

(52) U.S. Cl. 204/298.04

(57) ABSTRACT

Provided is a thin film forming apparatus that can focus ion beams onto a target and reduce a manufacturing cost. In a thin film forming apparatus radiating an ion beam (17) from an ion source (22) toward a target (6) and forming a thin film on a surface of a substrate (5) with particles sputtered by the ion beam, the ion source (22) includes an electrode for extracting ions from plasma and accelerating the extracted ions. The electrode includes a plate-shaped accelerator electrode (26) in which a plurality of accelerator apertures are bored, and a plate-shaped decelerator electrode (27) in which a plurality of decelerator apertures are bored. The plurality of accelerator apertures and the plurality of decelerator apertures are aligned and offset to focus the ion beams (17).

### BACKGROUND OF THE INVENTION

1. Field of the Invention

The present invention relates to a thin film forming apparatus for forming a film on a substrate in a fabrication process of a semiconductor device, and more particularly, to a thin film forming apparatus for forming a thin film using ion beam sputtering.

2. Description of the Prior Art

A thin film forming apparatus for forming a thin film using ion beam sputtering (hereinafter, referred to as an ion beam sputtering apparatus) can form a film in a high vacuum, as opposed to a thin film forming apparatus using a plasma discharge between a substrate and an electrode. An ion beam sputtering apparatus can also reduce the intrusion of contamination into a thin film, yielding a high quality thin film.

A conventional ion beam sputtering apparatus will be briefly described with reference to FIG. 7 and FIG. 8.

An ion source 2 is airtightly mounted on a sidewall of an airtight vacuum chamber 1. The ion source 2 is in communication with the vacuum chamber 1 through an ion radiation hole 3. A substrate holder 4 is installed in a lower portion inside the vacuum chamber 1 and supports a substrate 5 such as a wafer on which a thin film is to be formed.

A target 6 is installed above the substrate holder 4 horizontally from the ion radiation hole 3. The target 6 is obliquely installed to face both the ion radiation hole 3 and the substrate holder 4. The target 6 is made of the same material as a thin film to be formed on the substrate 5.

Also, a vacuum pump 7 is airtightly mounted on a sidewall of the vacuum chamber 1. The vacuum pump 7 can exhaust the vacuum chamber 1 to a negative pressure ranging from 10⁻⁴ Pa to 10⁻⁵ Pa.

A filament 8 is installed in the ion source 2, and multiaperture electrodes 9 and 10 are installed to face the filament 8 across the ion radiation hole 3 inside the ion source 2. Power is supplied to the filament 8 and rated voltages are applied to the multiaperture electrodes 9 and 10.

A gas source communicates with the ion source 2 and supplies gas to be ionized into the ion source 2, with the filament 8 electrified, triggering arc discharge between the filament 8 and a wall of the ion source 2 to generate plasma. Since argon (Ar) gas is normally used, Ar+ ions and electrons are mixed by the arc discharge. Ar+ ions are radiated through apertures of the multiaperture electrodes 9 and 10.

The Ar+ ions accelerated by the multiaperture electrodes 9 and 10 strike the target 6 as ion beams 17 with a kinetic energy. Sputtered particles are emitted from the target 6 and are deposited on the substrate, thereby forming a thin film thereon.

In the conventional ion beam sputtering apparatus, the ion beams 17 are radiated in parallel. Thus, the ion beams 17 are radiated over a wide area. The conventional ion beam sputtering apparatus also has a low current density on a target, yielding a slow film deposition rate. In addition, due to the ion beams 17 radiated over a wide area, the target 6 should be large, requiring that the ion beam sputtering apparatus also be large. Furthermore, other substances generated in the chamber may contaminate a substrate.

FIG. 9 and FIG. 10 illustrate another conventional ion beam sputtering apparatus that focuses ion beams radiated from the ion source 2. Since the ion beam sputtering apparatus illustrated in FIG. 9 and FIG. 10 has the same structure as the above-described ion beam sputtering apparatus, with the exception of an ion source 12, like reference numerals refer to like elements and description thereof will be omitted.

The ion source 12 of another conventional ion beam sputtering apparatus will be described hereinafter.

Each of multiaperture electrodes 13 and 14 inside the ion source 12 has a curved spherical surface that is concaved toward the target 6. Apertures 15 and 16 are bored in the multiaperture electrodes 13 and 14 and are aligned. In addition, the two aligned apertures 15 and 16 are located on the same axial center, which is directed to the center of curvature in the sphere.

Plasma is generated by supplying power to the filament 8, and Ar+ ions are accelerated by the multiaperture electrodes 13 and 14 and radiated through the apertures 15 and 16. Furthermore, the radiated ion beams 17 are focused due to the curvature of the multiaperture electrodes 13 and 14 and the directionality of the apertures 15 and 16.

Since the ion beams 17 are focused in the conventional ion beam sputtering apparatus illustrated in FIG. 9 and FIG. 10, the unfavorable conditions due to the parallel radiation of the ion beams 17 could be obviated. However, the material of the multiaperture electrodes 13 and 14 should be a refractory metal, such as molybdenum (Mo). A refractory alloy containing molybdenum (Mo) is difficult to process. In addition, since the multiaperture electrodes 13 and 14 should be formed in a curved shape and the formation of the apertures 15 and 16 requires an accurate three-dimensional placement, the manufacturing complexity and manufacturing cost increase. Furthermore, since the multiaperture electrodes 13 and 14 are curved, their thicknesses are increased and the dimensions of the ion source 12 in the direction of the axial center are also increased (Japanese Patent Publication No. 7-238372 for reference).

### SUMMARY OF THE INVENTION

Therefore, an object of the present invention is to provide a thin film forming apparatus that can focus ion beams onto a target and reduce a manufacturing cost.

According to the present invention, there is provided a thin film forming apparatus radiating an ion beam from an ion source toward a target and forming a thin film on a surface of a substrate with particles sputtered by the ion beam. The ion source includes an electrode for extracting ions from plasma and accelerating the extracted ions. The electrode includes a plate-shaped accelerator electrode in which a plurality of accelerator apertures are bored, and a plate-shaped decelerator electrode in which a plurality of decelerator apertures are bored. The plurality of accelerator apertures and the plurality of decelerator apertures are aligned and offset to focus the ion beams. Additionally, the plurality of accelerator apertures are arranged such that the center points of the adjacent accelerator apertures form a regular triangle. Furthermore, the plurality of decelerator apertures are offset outward from the center of the electrode with respect to the plurality of accelerator apertures.

### BRIEF DESCRIPTION OF THE DRAWINGS

FIG. 1 is a schematic cross-sectional view illustrating an ion beam sputtering apparatus according to an embodiment of the present invention.

FIG. 2 is an enlarged cross-sectional view illustrating an ion source according to an embodiment of the present invention.

FIG. 3 illustrates the deflection of an ion beam at an electrode according to an embodiment of the present invention.

FIG. 4 illustrates the positions of apertures of electrodes with respect to the center of an electrode.

FIG. 5 illustrates the relation between an electrode and a focused position of an ion beam.

FIG. 6 illustrates the placement of apertures in an electrode.

FIG. 7 is a schematic cross-sectional view illustrating a conventional ion beam sputtering apparatus.

FIG. 8 is an enlarged cross-sectional view illustrating an ion source used in the conventional ion beam sputtering apparatus of FIG. 7.

FIG. 9 is a schematic cross-sectional view illustrating another conventional ion beam sputtering apparatus.

FIG. 10 is an enlarged cross-sectional view illustrating an ion source used in the conventional ion beam sputtering apparatus of FIG. 9.

### DETAILED DESCRIPTION OF THE PREFERRED EMBODIMENTS

Hereinafter, preferred embodiments of the present invention will be described in detail with reference to the attached drawings.

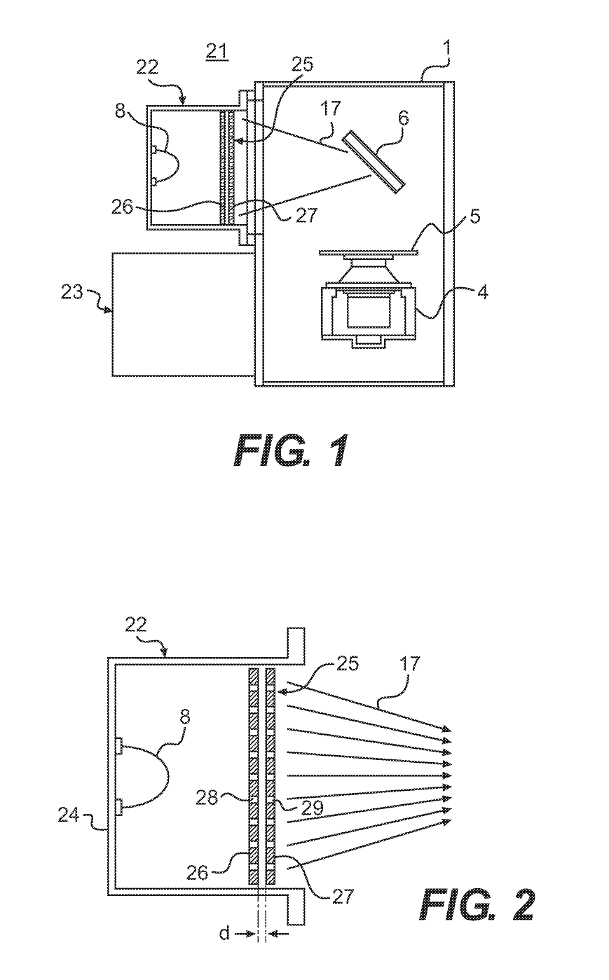

A thin film forming apparatus, for example, an ion beam sputtering apparatus in accordance with an embodiment of the present invention will be described with reference to FIG. 1.

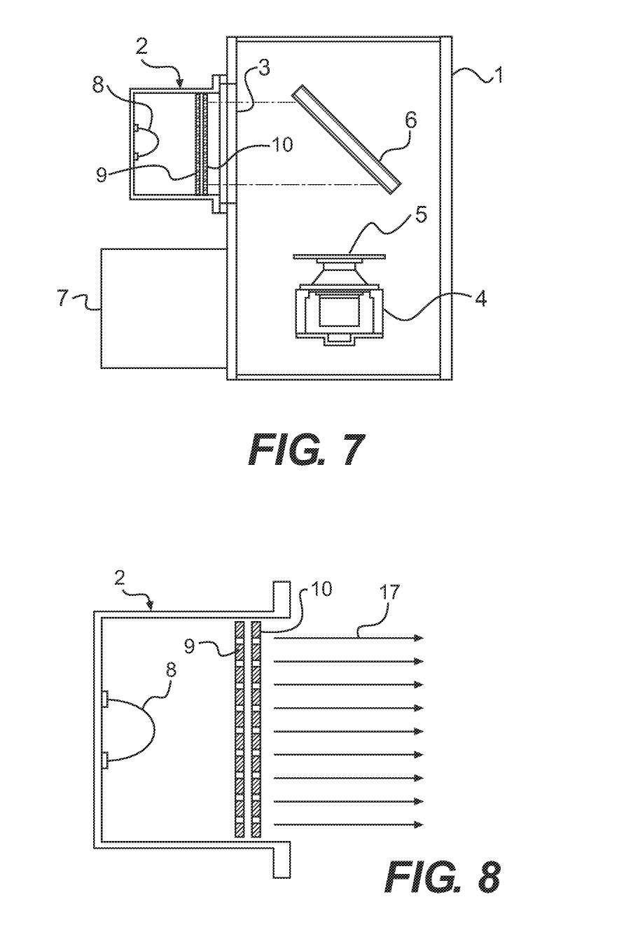

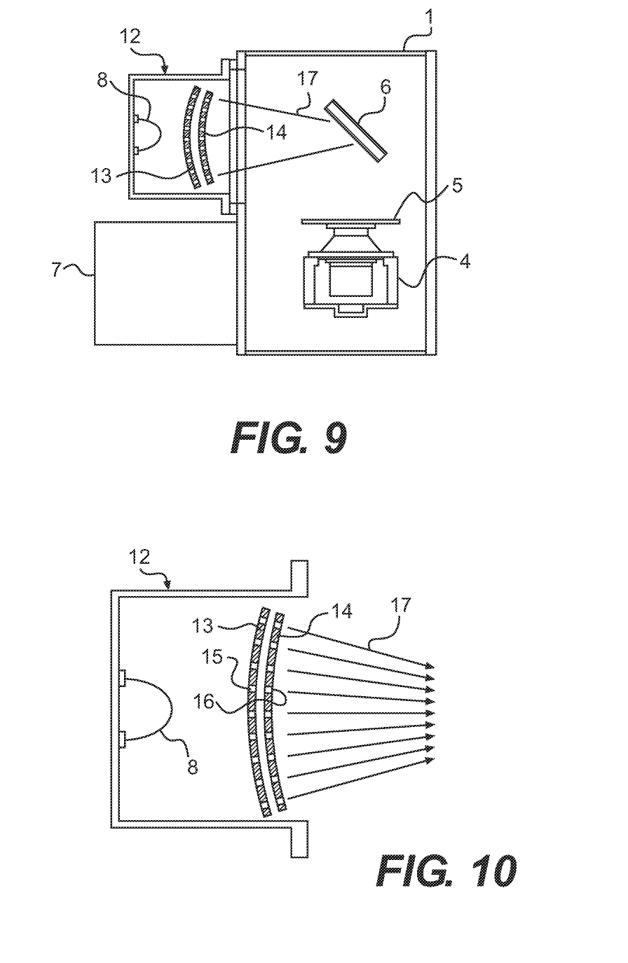

Since the basic structure of an ion beam sputtering apparatus 21 illustrated in FIG. 1 is the same as that illustrated in FIG. 7 and FIG. 8, like reference numerals refer to like elements and description thereof will be omitted.

An ion source 22 and an exhaust unit 23 are mounted on a sidewall of a vacuum chamber 1, and a substrate 5 is installed within the vacuum chamber 1. A target 6 is obliquely installed to face both the substrate 5 and the ion source 22.

The exhaust unit 23 includes a vacuum pump and exhausts the vacuum chamber 1 to a negative pressure ranging from 10⁻⁴ Pa to 10⁻⁵ Pa.

A gas to be ionized is supplied to the ion source 22 and ions are generated by plasma. The ions are radiated as focused ion beams 17 from the ion source 22, and the ion beams 17 strike the target 6. Sputtered particles are emitted from the target 6 and are deposited on the substrate 5, thereby forming a thin film thereon.

FIG. 2 illustrates the ion source 22 of the ion beam sputtering apparatus 21 according to the embodiment of the present invention. The ion source 22 includes an ion source chamber 24 airtightly mounted on a sidewall of the vacuum chamber 1, a filament 8 installed on a lower portion of the ion source chamber 24, and an electrode 25 facing the filament 8. The electrode 25 is made of a refractory metal, such as molybdenum (Mo).

The electrode 25 includes a plate-shaped accelerator electrode 26 and a plate-shaped decelerator electrode 27. The accelerator electrode 26 and the decelerator electrode 27 are arranged in parallel and separated by a distance d. A plurality of accelerator apertures 28 are bored in the accelerator electrode 26 and a plurality of decelerator apertures 29 are bored in the decelerator electrode 27.

Ions are extracted and accelerated by the electrode 25 and are radiated as the ion beams 17. In addition, the electrode 25 functions to focus the ion beams 17.

The ion beam focusing function of the electrode 25 is achieved by ion beam deflection through offsetting the corresponding accelerator aperture 28 and decelerator aperture 29.

Hereinafter, the electrode 25 will be described in more detail.

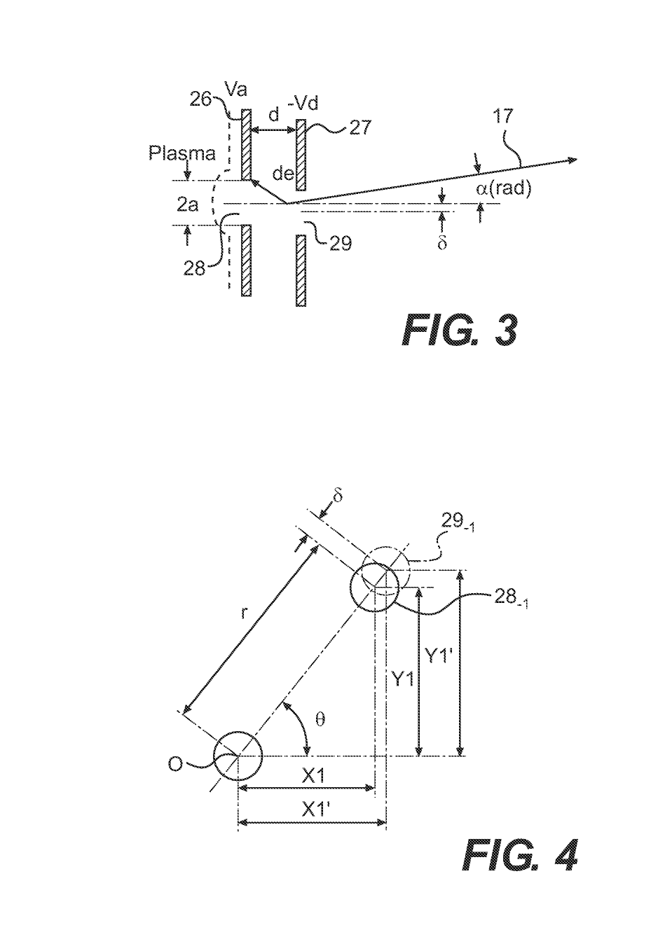

FIG. 3 schematically illustrates the accelerator electrode 26, the decelerator electrode 27, the accelerator aperture 28, and the decelerator aperture 29.

When the decelerator aperture 29 is offset from the accelerator aperture 28 by 6 , the ion beam 17 passing through the accelerator aperture 28 and the decelerator aperture 29 is deflected at an angle a opposite to the offset direction of the decelerator aperture 29.

When assuming that Va is a voltage applied to the accelerator electrode 26, −Vd is a voltage applied to the decelerator electrode 27, 2a is a diameter of the accelerator aperture 28 and the decelerator aperture 29, 6 is an aperture displacement between the accelerator aperture 28 and the decelerator aperture 29, and de is an effective acceleration length, the deflection angle a of the ion beam 17 is expressed as the following equation, called Kaufman's empirical formula.

α≐33·δ/de·1/√(R) (Eq. 1)

where R=Va/(Va+|Vd|) (Eq. 2)

d/2a(aspect ratio)<1 (Eq. 3)

It can be experimentally found that divergence of the ion beam 17 is small when the value of R is in the range of 0.9 to 0.95.

Therefore, the deflection angle α, that is, the aperture displacement δ, is adjusted to direct the ion beams 17 passing through the accelerator apertures 28 and the decelerator apertures 29 to a predetermined focal point. For the accelerator apertures 28 and the decelerator apertures 29 located proximal to the center of the electrode 25, the aperture displacement δ is set to a small value. For the accelerator apertures 28 and the decelerator apertures 29 located distal from the center of the electrode 25, the aperture displacement δ is set to a large value. That is, the aperture displacement δ increases as the apertures are getting farther from the center of the electrode 25.

FIG. 4 illustrates the relation between positions of the accelerator aperture 28 and the decelerator aperture 29 with respect to the center of the electrode 25, and the aperture displacement δ of the accelerator aperture 28 and the decelerator aperture 29.

That is, when assuming that (X1, Y1) is coordinates of an accelerator aperture 28-1 located at an angle ⊖ from the center 0 of the electrode at a distance r, and (X1′, Y1′) is coordinates of a decelerator aperture 29-1, the following equations are satisfied.

θ=tan⁻¹(|X1|/|Y1|) (Eq. 4)

(X1′, Y1′)=((X1+δcosθ), (Y1+δsinθ)) (Eq. 5)

Also, when the ion beam 17 is focused at a distance F from the decelerator electrode 27 along the axial center of the accelerator electrode 26,

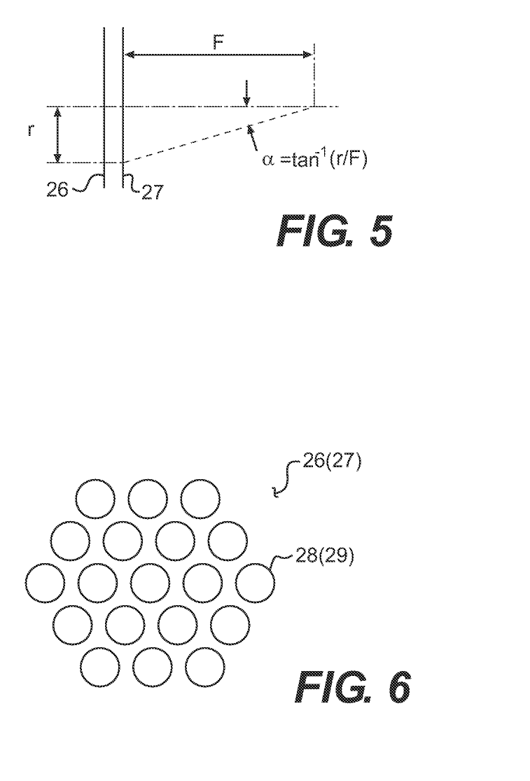

α=tan⁻¹(r/F)=tan⁻¹(√(X1²+Y1²)/F) (Eq. 6) (see FIG. 5).

Therefore, by obtaining the coordinates X1 and Y1 satisfying the equations 1 to 6 and forming the accelerator aperture 28 and the decelerator aperture 29 in accordance with the coordinates, the ion beam 17 can be focused on a desired position.

FIG. 6 illustrates one example of the arrangement of the accelerator apertures 28 and the decelerator apertures 29.

Referring to FIG. 6, the accelerator apertures 28 and the decelerator apertures 29 are positioned at apexes of a regular hexagon and around the apexes. The center points of three adjacent apertures form a regular triangle, and the adjacent apertures have the same spacing. According to the aperture arrangement of FIG. 6, the ion beams 17 have the uniform beam density because of the same spacing of the adjacent apertures.

In one modification of the above-mentioned embodiment, the substrate holder 4 may be installed above the target 6. If the substrate holder 4 is installed above the target 6, a thin film is formed on a surface of the substrate 5, and foreign particles generated when the ion beams 17 are radiated onto regions other than the target 6 are hardly attached to the substrate 5.

Also, the angle and position of the target 6 with respect to the electrode 25 and the substrate 5 can be optimized depending on the kind and material of a film. In addition, the target 6 may have a plurality of surfaces to be radiated, respectively made of different materials. Thus, different films can be formed by the ion beam sputtering on the respective surfaces of the target 6.

Furthermore, a variety of films can be formed when the target 6 is formed in a polyhedral shape, such as a hexahedron or the like, each surface of which is made of a different material.

Moreover, if a substrate rotating mechanism is provided to the substrate holder 4 and rotates the substrate 5 at a constant speed in a film forming process, the film quality can be further improved.

A material of the target 6 is selected in accordance with the film forming process. For example, when forming a metal film or an insulation film, titanium, alumina or the like is selected as the target material. When forming a film for a Magnetoresistive Random Access Memory (MRAM), nickel, iron, magnesium oxide or the like is selected as the target material.

According to the present invention described above, the ion beams 17 are focused and the ion beam density (current density) is increased, resulting in the increase of the film deposition rate. Since both the accelerator electrode 26 and the decelerator electrode 27 are plate-shaped, their processing is simplified and the manufacturing cost is reduced. Additionally, since the manufacturing cost of the consumable electrode 25 is reduced, the running cost is also reduced. Moreover, the target and the ion source can be miniaturized to allow the miniaturization of the thin film forming apparatus. Furthermore, since the ion beams are focused onto the target, the generation of foreign particles from components of the thin film forming apparatus is suppressed, thereby preventing the contamination of the substrates.

According to the present invention, the thin film forming apparatus radiates an ion beam from an ion source toward a target and forms a thin film on a surface of a substrate with particles sputtered by the ion beam. The ion source includes an electrode for extracting ions from plasma and accelerating the extracted ions. The electrode includes a plate-shaped accelerator electrode in which a plurality of accelerator apertures are bored, and a plate-shaped decelerator electrode in which a plurality of decelerator apertures are bored. The plurality of accelerator apertures and the plurality of decelerator apertures are aligned and offset to focus the ion beams. Additionally, the plurality of accelerator apertures are arranged such that the center points of the adjacent accelerator apertures form a regular triangle. Furthermore, the plurality of decelerator apertures are offset outward from the center of the electrode with respect to the plurality of accelerator apertures. Therefore, the ion beam density (current density) is increased, resulting in the increase of the film deposition rate. Because both the accelerator electrode and the decelerator electrode are plate-shaped, their processing is simplified and the manufacturing cost is reduced. Additionally, since the manufacturing cost of the consumable electrode is reduced, the running cost is also reduced. Moreover, the target and the ion source are miniaturized to allow the miniaturization of the thin film forming apparatus. Furthermore, since the ion beams are focused onto the target, the generation of foreign particles from components of the thin film forming apparatus is suppressed, thereby preventing the contamination of the substrates.

### (Supplementary Note)

The present invention also includes the following embodiments.

### (Supplementary Note 1)

A thin film forming apparatus radiating an ion beam from an ion source toward a target and forming a thin film on a surface of a substrate with particles sputtered by the ion beam, wherein the ion source includes an electrode for extracting ions from plasma and accelerating the extracted ions, the electrode including: a plate-shaped accelerator electrode in which a plurality of accelerator apertures are bored; and a plate-shaped decelerator electrode in which a plurality of decelerator apertures are bored, wherein the plurality of accelerator apertures and the plurality of decelerator apertures are aligned and offset to focus the ion beams.

### (Supplementary Note 2)

The thin film forming apparatus of the Supplementary Note 1, wherein the decelerator apertures are offset outward from the center of the electrode with respect to the accelerator apertures.

### (Supplementary Note 3)

The thin film forming apparatus of the Supplementary Note 2, wherein an aperture displacement increases as the decelerator apertures are getting farther from the center of the electrode.

(Supplementary Note 4) The thin film forming apparatus of the Supplementary Note 1, wherein when the center of the electrode is the origin of the XY coordinates, the accelerator aperture is located at (X1, Y1), and the decelerator aperture is located at (X1′, Y1′), the placement of the accelerator aperture and the decelerator aperture satisfies the following equations 1 to 6.

α≐33·δ/de·1/√(R) (Eq. 1)

R=Va/(Va+|Vd|) (Eq. 2)

d/2a(aspect ratio)<1 (Eq. 3)

θ=tan⁻¹(|X1|/|Y1|) (Eq. 4)

(X1′, Y1′)=((X1+δcosθ), (Y1+δsinθ)) (Eq. 5)

α=tan⁻¹(r/F)=tan⁻¹(√(X1²+Y1²)/F) (Eq. 6)

where,
Va: a voltage applied to the accelerator electrode
−Vd: a voltage applied to the decelerator electrode
δ: an aperture displacement between the accelerator aperture and the decelerator aperture
d: a distance between the accelerator electrode and the decelerator electrode
2a: a diameter of the accelerator electrode and the decelerator electrode
α: a deflection angle of the ion beam
de: an effective acceleration length
F: a focused position of the ion beam on an axial center of the electrode
θ: a direction of the accelerator aperture and the decelerator aperture with respect to the center O of the electrode
   (Supplementary Note 5) The thin film forming apparatus of the Supplementary Note 1, wherein the target has a plurality of surfaces to be radiated, respectively made of different materials.

(Supplementary Note 6) The thin film forming apparatus of the Supplementary Note 1, further comprising a substrate holder to support the substrate, wherein the substrate holder includes a substrate rotating mechanism to rotate the substrate during a film forming process.

What is claimed is:

1. A thin film forming apparatus radiating an ion beam from an ion source toward a target and forming a thin film on a surface of a substrate with particles sputtered by the ion beam,
wherein the ion source includes an electrode for extracting ions from plasma and accelerating the extracted ions, the electrode including:
a plate-shaped accelerator electrode in which a plurality of accelerator apertures are bored; and
a plate-shaped decelerator electrode in which a plurality of decelerator apertures are bored,
wherein the plurality of accelerator apertures and the plurality of decelerator apertures are aligned and offset to focus the ion beams.

2. The thin film forming apparatus of claim 1, wherein the plurality of accelerator apertures are arranged such that the center points of the adjacent accelerator apertures form a regular triangle.

3. The thin film forming apparatus of claim 1, wherein the plurality of decelerator apertures are offset outward from the center of the electrode with respect to the plurality of accelerator apertures.
